(19) United States
(12) Patent Application Publication
(10) Pub. No.: US 2026/0107495 A1
(43) Pub. Date: Apr. 16, 2026

(54) TWO-DIMENSIONAL MATERIAL GROWTH SUBSTRATE AND SEMICONDUCTOR DEVICE USING THE SAME

(71) Applicant: Samsung Electronics Co., Ltd., Suwon-si (KR)

(72) Inventors: Sangmin Kang, Suwon-si (KR); Jinwon Ma, Suwon-si (KR); Suk Yang, Suwon-si (KR)

(73) Assignee: Samsung Electronics Co., Ltd., Suwon-si (KR)

(21) Appl. No.: 19/343,383

(22) Filed: Sep. 29, 2025

(30) Foreign Application Priority Data
Oct. 16, 2024 (KR) 10-2024-0141455

(51) Int. Cl. H10D 30/47; H10D 30/01; H10D 30/69; H10D 62/80

(52) U.S. Cl. CPC H10D 30/481; H10D 30/017; H10D 30/792; H10D 30/798; H10D 62/882; H10D 62/883

(57) ABSTRACT

A two-dimensional (2D) material growth substrate includes a semiconductor substrate having a first surface and a second surface opposite to the first surface; a strain control buffer layer formed on the second surface of the semiconductor substrate; a surface protective layer formed on the first surface of the semiconductor substrate; and a 2D material layer formed on the surface protective layer. The 2D material layer is configured to generate one of a tensile strain and a compressive strain. The semiconductor substrate and the strain control buffer layer include materials having different thermal expansion coefficients, and a combined thermal expansion coefficient of the semiconductor substrate and the strain control buffer layer is substantially similar to a thermal expansion coefficient of the 2D material layer.

### CROSS-REFERENCE TO RELATED APPLICATION

This application is based on and claims priority under 35 U.S.C. § 119 to Korean Patent Application No. 10-2024-0141455, filed on Oct. 16, 2024, in the Korean Intellectual Property Office, the disclosure of which is incorporated by reference herein in its entirety.

### TECHNICAL FIELD

The present disclosure relates to a two-dimensional (2D) material growth substrate and a semiconductor device using the same, and more particularly, to a 2D material growth substrate having a structure suitable for use in a process of manufacturing a semiconductor device with excellent reliability, and a semiconductor device using the 2D material growth substrate.

### BACKGROUND

A transistor, which is a semiconductor device configured to perform a function of electrical switching, is used in various semiconductor products such as a memory, a driving integrated circuit (IC), etc. As the semiconductor device has a reduced size, the number of semiconductor devices that can be integrated into one wafer may increase, and also a driving speed of the semiconductor device may increase. Thus, research into reducing the size of the semiconductor device has been actively conducted. Recently, as a method of reducing the size of the semiconductor device, research into using a two-dimensional (2D) material has been performed. Even with a small thickness of 1 nm or less, the 2D material has stable and superb characteristics, and thus, has drawn attention as a material to overcome the limit of performance deterioration according to the reduced size of the semiconductor device.

### SUMMARY

The disclosed embodiments provide a semiconductor device using a two-dimensional (2D) material growth substrate, which may improve the electrical characteristics by using strain generated by the difference between thermal expansion coefficients of materials.

The objectives of the present disclosure are not limited to those mentioned above, and other unmentioned objectives will be clearly understood by one of ordinary skill in the art from the descriptions below.

According to an aspect of the present disclosure, there is provided a 2D material growth substrate including a semiconductor substrate having a front-side surface (e.g., a first surface) and a back-side surface (e.g., a second surface) that are opposite each other, a strain control buffer layer formed on the back-side surface of the semiconductor substrate, a surface protective layer formed on the front-side surface of the semiconductor substrate, and a 2D material layer formed on the surface protective layer, wherein the semiconductor substrate and the strain control buffer layer include materials having different thermal expansion coefficients, and the 2D material layer creates one of tensile strain and compressive strain.

According to another aspect of the present disclosure, there is provided a method of manufacturing a 2D material growth substrate, the method including preparing a semiconductor substrate having a front-side surface and a back-side surface that are opposite each other, forming a strain control buffer layer having a selected thickness on the back-side surface of the semiconductor substrate, applying a dopant onto an interface between the semiconductor substrate and the strain control buffer layer, forming a surface protective layer on the front-side surface of the semiconductor substrate, and forming a 2D material layer on the surface protective layer, wherein the semiconductor substrate and the strain control buffer layer include materials having different thermal expansion coefficients.

According to another aspect of the present disclosure, there is provided a semiconductor device including a semiconductor substrate having a front-side surface and a back-side surface that are opposite each other, a strain control buffer layer formed on the back-side surface of the semiconductor substrate, a surface protective layer formed on the front-side surface of the semiconductor substrate, a 2D material layer formed on the surface protective layer, a first electrode and a second electrode formed on the 2D material layer, a gate electrode formed between the first electrode and the second electrode, and a gate dielectric layer formed between the 2D material layer and the gate electrode, wherein the semiconductor substrate and the strain control buffer layer include materials having different thermal expansion coefficients, and the 2D material layer creates one of tensile strain and compressive strain.

### BRIEF DESCRIPTION OF THE DRAWINGS

Embodiments will be more clearly understood from the following detailed description taken in conjunction with the accompanying drawings in which:

FIG. 1 is a perspective view of a two-dimensional (2D) material growth substrate according to an embodiment;

FIG. 2 is a cross-sectional view of a 2D material growth substrate according to an embodiment;

FIG. 3 is a conceptual diagram of a grid structure of a 2D material growth substrate according to a comparative embodiment;

FIGS. 4 and 5 are conceptual diagrams of a grid structure of a 2D material growth substrate according to an embodiment;

FIGS. 6 and 7 are cross-sectional views of a 2D material growth substrate according to another embodiment;

FIG. 8 is a flowchart of a method of manufacturing a 2D material growth substrate, according to an embodiment;

FIGS. 9 to 14 are cross-sectional views in a process order for describing a method of manufacturing a 2D material growth substrate, according to an embodiment; and

FIG. 15 is a cross-sectional view of a semiconductor device according to an embodiment.

### DETAILED DESCRIPTION OF THE EMBODIMENTS

Hereinafter, embodiments will be described in detail by referring to the accompanying drawings.

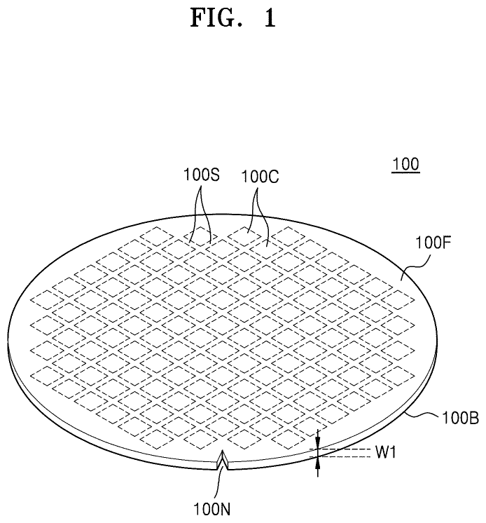

FIG. 1 is a perspective view of a two-dimensional (2D) material growth substrate 100 according to an embodiment.

FIG. 1 illustrates the 2D material growth substrate 100 including a semiconductor device area 100C and a cutting area 100S consistent with embodiments of the present disclosure.

The 2D material growth substrate 100 may include a circular wafer having a thickness W1. The 2D material growth substrate 100 may include a notch 100N used as a reference point for wafer alignment.

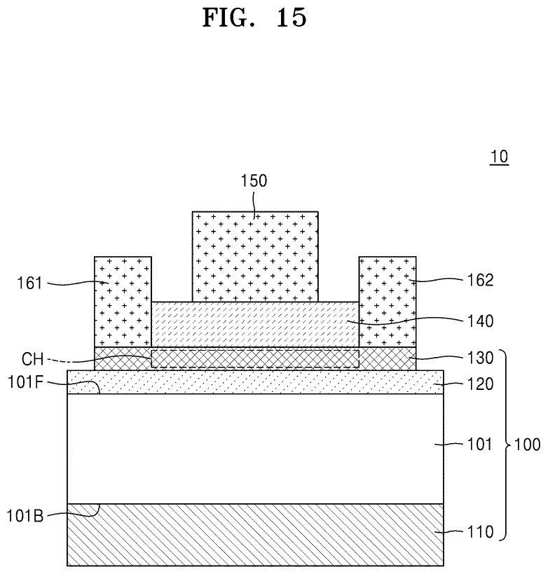

Here, it is assumed that the 2D material growth substrate 100 has a diameter of about 12 inches. However, it may be understood by one of ordinary skill in the art that it is possible to use the 2D material growth substrate 100 having a diameter of less than or greater than about 12 inches. Also, the 2D material growth substrate 100 may have a thickness W1 of about 0.1 mm to about 1 mm. When the thickness W1 of the 2D material growth substrate 100 is too small, mechanical strength may be insufficient, and when the thickness W1 of the 2D material growth substrate 100 is too great, the productivity of a semiconductor device 10 (see FIG. 15) may decrease.

The 2D material growth substrate 100 may include an active surface 100F, which is a front-side surface (which may also be referred to as a first surface), and a non-active surface 100B, which is a back-side surface (which may also be referred to as a second surface). A plurality of semiconductor device areas 100C, each of which is to be separated into the semiconductor device 10 (see FIG. 15), may be formed on the active surface 100F.

The plurality of semiconductor device areas 100C may be arranged to be partitioned from each other by the cutting area 100S. The cutting area 100S may be referred to as a scribe lane. For example, the plurality of semiconductor device areas 100C may be surrounded in four directions by the cutting area 100S and may be spaced apart from each other. The plurality of semiconductor device areas 100C may be separated into the plurality of semiconductor devices 10 (see FIG. 15), respectively, by cutting the 2D material growth substrate 100 and various types of material layers formed on the 2D material growth substrate 100 in a cutting process performed along the cutting area 100S.

Various types of material layers included in the 2D material growth substrate 100 according to an embodiment and the characteristics thereof are to be described below.

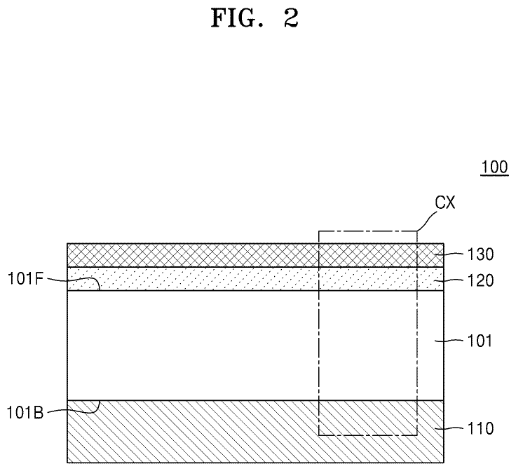

FIG. 2 is a cross-sectional view of the 2D material growth substrate 100 according to an exemplary embodiment.

Referring to FIG. 2, the 2D material growth substrate 100 may include a semiconductor substrate 101.

The semiconductor substrate 101 may include any one material selected from a first group including silicon (Si), silicon oxide, silicon nitride, silicon carbide, sapphire, and metal oxide.

According to some embodiments, the semiconductor substrate 101 may include a monocrystalline semiconductor material. For example, the semiconductor substrate 101 may include a wafer including a semiconductor material, such as Si, as a monocrystalline type. The semiconductor substrate 101 may include a Group III element or a Group V element as impurities. For example, the Group III element may include boron (B) and the Group V element may include phosphorus (P).

For growing an ingot, the semiconductor substrate 101 may include a Group III element or a Group V element. For example, a Si ingot including boron (B) may be grown as a certain size and the ingot may be sliced to obtain the semiconductor substrate 101.

A strain control buffer layer 110 may be arranged on the back-side surface 101B of the semiconductor substrate 101. The strain control buffer layer 110 may be formed by using at least one of a chemical vapor deposition (CVD) process, a low-pressure CVD process, a plasma-enhanced CVD process, an organic metal CVD process, an atomic layer deposition (ALD) process, and an epitaxial process.

In some embodiments, the strain control buffer layer 110 may include another material selected from the first group including Si, silicon oxide, silicon nitride, silicon carbide, sapphire, and metal oxide. For example, the semiconductor substrate 101 and the strain control buffer layer 110 may include materials having different thermal expansion coefficients. This aspect will be described in detail below.

A surface protective layer 120 may be arranged on the front-side surface 101F of the semiconductor substrate 101. The surface protective layer 120 may perform a function of resolving defects on the front-side surface 101F of the semiconductor substrate 101. For example, the surface protective layer 120 may reduce the effect by a crystalline edge surface by removing the dangling bond formed on the front-side surface 101F of the semiconductor substrate 101.

According to some embodiments, the surface protective layer 120 may include an oxide layer. In particular, when the semiconductor substrate 101 includes a semiconductor material, such as Si, as a monocrystalline type, the surface protective layer 120 may include a silicon oxide layer. For example, the silicon oxide layer may include silicon dioxide (SiO₂), borosilicate glass (BSG), phosphosilicate glass (PSG), borophosphosilicate glass (BPSG), undoped silicate glass (USG), tetraethylorthosilicate glass (TEOS), or a combination thereof, but is not limited thereto. Also, the surface protective layer 120 may include the oxide layer formed by any one process selected from among a thermal oxidation process, a plasma oxidation process, and a wet oxidation process.

A 2D material layer 130 may be arranged on a front-side surface of the surface protective layer 120. The 2D material layer 130 may denote a semiconductor or semi-metal having a layer structure in which atoms are two-dimensionally combined. The 2D material layer 130 may have excellent electrical properties, and even with small nanoscale thickness, this characteristic may not greatly change, and high electron mobility may be maintained.

The 2D material layer 130 may include a material having a bandgap of about 0.1 eV to about 3.0 eV, but is not limited thereto. For example, the 2D material layer 130 may include transition metal dichalcogenide, black phosphorus, or graphene, but is not limited thereto.

The transition metal dichalcogenide is a compound of a transition metal and a chalcogen element. The transition metal may include, for example, at least one of molybdenum (Mo), tungsten (W), niobium (Nb), tin (Sn), vanadium (V), tantalum (Ta), titanium (Ti), zirconium (Zr), hafnium (Hf), technetium (Tc), and rhenium (Re). The chalcogen element may include, for example, at least one of sulfur(S), selenium (Se), and tellurium (Te). For example, the transition metal dichalcogenide may include any one material selected from the group including sulfides (e.g., compounds containing S₂), selenides (e.g., compounds containing Se₂), or tellurides (e.g., compounds containing Te₂), such as, MoS₂, WS₂, TaS₂, HfS₂, ReS₂, TiS₂, NbS₂, SnS₂, MoSe₂, WSe₂, TaSe₂, HfSe₂, ReSe₂, TiSe₂, NbSe₂, SnSe₂, MoTe₂, WTe₂, TaTe₂, HfTe₂, ReTe₂, TiTe₂, NbTe₂, and SnTe₂, but is not limited thereto.

The black phosphorus is a 2D material in which phosphorus atoms are two-dimensionally combined. The graphene is a 2D material in which carbon atoms are two-dimensionally combined.

The 2D material layer 130 may have a monolayer structure or a multilayer structure, and each layer may have an atomic level thickness. The 2D material layer 130 may include, for example, one to ten layers, but is not limited thereto.

The 2D material layer 130 may further include a certain dopant for controlling electron mobility. For example, the 2D material layer 130 may be doped with a p-type dopant or an n-type dopant. The p-type dopant or the n-type dopant may be doped by ion implantation or chemical doping.

The source of the p-type dopant may include, for example, an ionic liquid, such as NO₂BF₄, NOBF₄, and NO₂SbF₆; an acidic compound, such as HCl, H₂PO₄, CH₃COOH, H₂SO₄, and HNO₃; and an organic compound, such as dichlorodicyanoquinone, oxone, dimyristoylphosphatidylinositol, and trifluoromethanesulfoneimide. Alternatively, the source of the p-type dopant may include HPtCl₄, AuCl₃, HAuCl₄, AgOTf (silver trifluoromethanesulfonate), AgNO₃, H₂PdCl₆, Cu(CN)₂, etc.

The source of the n-type dopant may include, for example, a reduction product of a substituted or unsubstituted nicotinamide, a reduction product of a compound which is chemically bound to a substituted or unsubstituted nicotinamide, and a compound including at least two pyridinium moieties in which a nitrogen atom of at least one of the pyridinium moieties is reduced. For example, the source of the n-type dopant may include nicotinamide mononucleotide-H (NMNH), nicotinamide adenine dinucleotide-H (NADH), nicotinamide adenine dinucleotide phosphate-H (NADPH), or viologen. Alternatively, the source of the n-type dopant may include a polymer, such as polyethylenimine (PEI).

As described above, the 2D material growth substrate 100 according to an embodiment may control the electrical characteristics by using, for the 2D material layer 130, the strain generated due to the difference between thermal expansion coefficients of materials according to the strain control buffer layer 110 formed on the back-side surface 101B of the semiconductor substrate 101. Detailed aspects with respect to controlling of the strain according to an embodiment will be described below.

As a result, through the substrate structure described above, the 2D material growth substrate 100 according to an embodiment may be used for manufacturing the semiconductor device 10 (see FIG. 15) having high integration and excellent electrical characteristics.

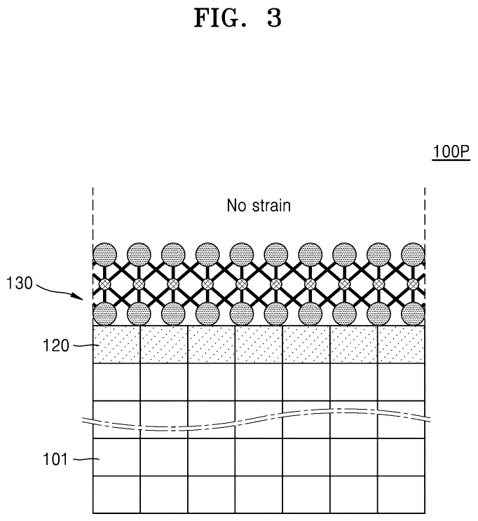

FIG. 3 is a conceptual diagram of a grid structure of a 2D material growth substrate 100P according to a comparative embodiment.

Referring to FIG. 3, the strain control buffer layer 110, which is a physical element capable of changing a grid state of a material included in the semiconductor substrate 101, may not be formed on a back-side surface of the semiconductor substrate 101, and the 2D material layer 130 may be formed on a front-side surface of the semiconductor substrate 101.

Thus, as illustrated in FIG. 3, tensile strain or compressive strain may not be applied between the semiconductor substrate 101 and the 2D material layer 130. For example, the 2D material layer 130 may be arranged on the front-side surface of the semiconductor substrate 101, while no strain is being applied thereto.

However, when semiconductor substrate 101 and the 2D material layer 130 are cooled, undesired tensile strain or compressive strain may be applied to the 2D material layer 130 due to the difference between a thermal expansion coefficient of the material included in the semiconductor substrate 101 and a thermal expansion coefficient of a material included in the 2D material layer 130, in a cooling process, which is one process of a manufacturing process of the semiconductor device 10 (see FIG. 15).

In general, the type of the dopant (the n-type or the p-type), with which the 2D material layer 130 is doped, may affect the electrical characteristics of the semiconductor device 10 (see FIG. 15). Thus, in the semiconductor device 10 (see FIG. 15) using the 2D material layer 130 as a channel region of a cell transistor, undesired tensile strain or compressive strain (or tensile strain or compressive strain in a direction opposite to a desired direction) may be applied to the 2D material layer 130, and this may cause defects so that it may be difficult to manufacture a highly reliable semiconductor device.

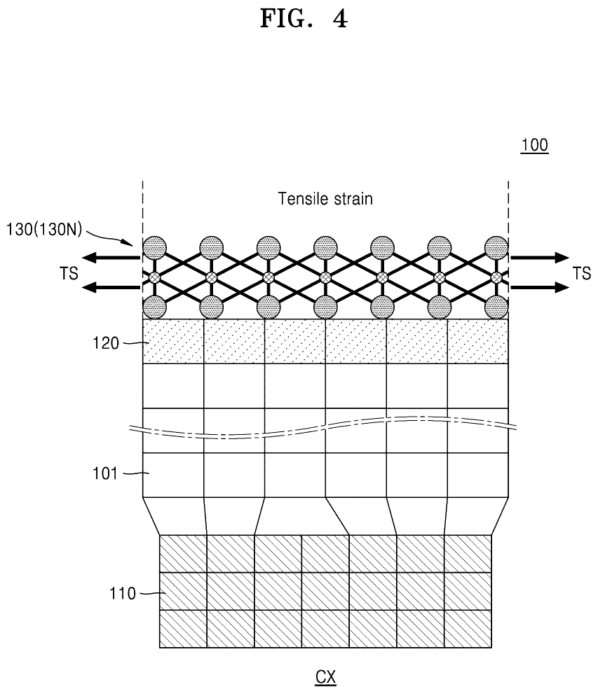

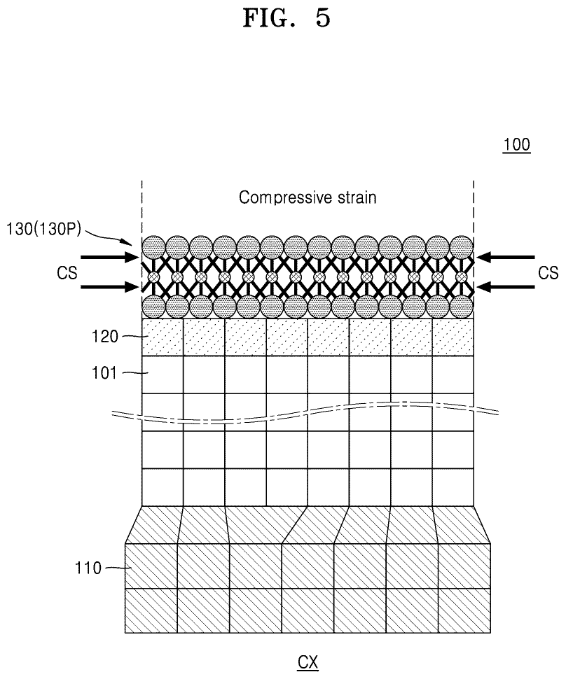

FIGS. 4 and 5 are conceptual diagrams of a grid structure of the 2D material growth substrate 100 according to an exemplary embodiment. In detail, each of FIGS. 4 and 5 is an enlarged cross-sectional view of region CX of FIG. 2.

Referring to FIGS. 4 and 5 together, the strain control buffer layer 110 may be formed on the back-side surface 101B of the semiconductor substrate 101 and the 2D material layer 130 may be formed on the front-side surface 101F of the semiconductor substrate 101.

For each of the semiconductor substrate 101 and the strain control buffer layer 110 included in the 2D material growth substrate 100 to apply desired tensile strain TS or compressive strain CS to the 2D material layer 130, the following conditions may have to be satisfied.

A first thermal expansion coefficient of the material included in the semiconductor substrate 101 may be different from a second thermal expansion coefficient of the material included in the strain control buffer layer 110. For example, the material included in the semiconductor substrate 101 may be different from the material included in the strain control buffer layer 110.

A first thickness of the semiconductor substrate 101 may be different from a second thickness of the strain control buffer layer 110. For example, the second thickness may be less than the first thickness, in consideration of the warpage of the semiconductor substrate 101.

By forming the strain control buffer layer 110 having a selected thickness (or second thickness) and including a material different from the material of the semiconductor substrate 101, a fourth thermal expansion coefficient may be obtained by combining the semiconductor substrate 101 and the strain control buffer layer 110. In other words, through a back-side engineering process, the semiconductor substrate 101 and the strain control buffer layer 110 may have the fourth thermal expansion coefficient, which is substantially the same as or similar to a third thermal expansion coefficient of the material included in the 2D material layer 130. Two thermal expansion coefficients may be deemed to be substantially the same or similar if the difference between the two thermal expansion coefficients is less than about 1% to 5%.

In this case, a desired tensile strain TS or compressive strain CS may be provided to the 2D material layer 130 due to the presence of the strain control buffer layer 110, and thus, the 2D material layer 130 may have a tensile strain (see FIG. 4) or a compressive strain (see FIG. 5) after formation of the 2D material growth substrate 100.

According to some embodiments, as illustrated in FIG. 4, the 2D material layer 130 may be doped with an n-type dopant and may form an n-type 2D material layer 130N having a property of an n-type semiconductor. In this case, strain to increase the mobility of electrons is required. Thus, by applying the tensile strain TS to the n-type 2D material layer 130N, the 2D material growth substrate 100 including the n-type 2D material layer 130N having the tensile strain may be formed.

In the subsequent cooling process, undesired strain may not be applied to the n-type 2D material layer 130N because the fourth thermal expansion coefficient obtained by combining the semiconductor substrate 101 and the strain control buffer layer 110 may be substantially the same as or similar to the third thermal expansion coefficient of the n-type 2D material layer 130N. For example, a desired tensile strain may be provided to the n-type 2D material layer 130N through the back-side engineering process due to the presence of the strain control buffer layer 110 and that tensile strain may not be undesirably altered when semiconductor substrate 101 and the 2D material layer 130N are cooled during the manufacturing process.

According to other exemplary embodiments, as illustrated in FIG. 5, the 2D material layer 130 may be doped with a p-type dopant and may form a p-type 2D material layer 130P having a property of a p-type semiconductor. In this case, strain to increase the mobility of holes is required. Thus, by applying the compressive strain CS to the p-type 2D material layer 130P, the 2D material growth substrate 100 including the p-type 2D material layer 130P having the compressive strain may be formed.

In the subsequent cooling process, undesired strain may not be applied to the p-type 2D material layer 130P because the fourth thermal expansion coefficient obtained by combining the semiconductor substrate 101 and the strain control buffer layer 110 may be substantially the same as or similar to the third thermal expansion coefficient of the p-type 2D material layer 130P. For example, a desired compressive strain may be provided to the p-type 2D material layer 130P through the back-side engineering process due to the presence of the strain control buffer layer 110 and that compressive strain may not be undesirably altered when semiconductor substrate 101 and the 2D material layer 130P are cooled during the manufacturing process.

The 2D material growth substrate 100 according to an embodiment may control the electrical characteristics by using, for the 2D material layer 130, the strain generated due to the difference between the thermal expansion coefficients of materials according to the strain control buffer layer 110 formed on the back-side surface 101B of the semiconductor substrate 101.

As a result, through the substrate structure described above, the 2D material growth substrate 100 may be used for manufacturing the semiconductor device 10 (see FIG. 15) having high integration and excellent electrical characteristics.

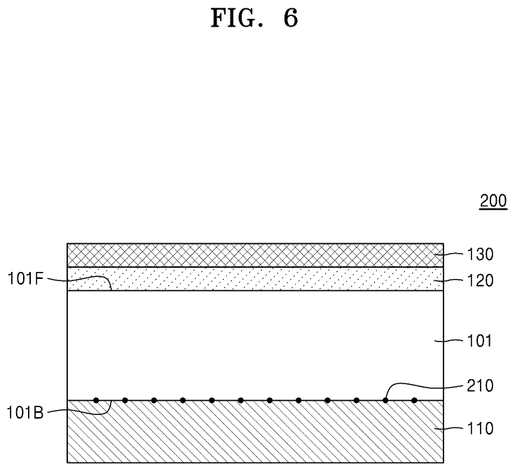

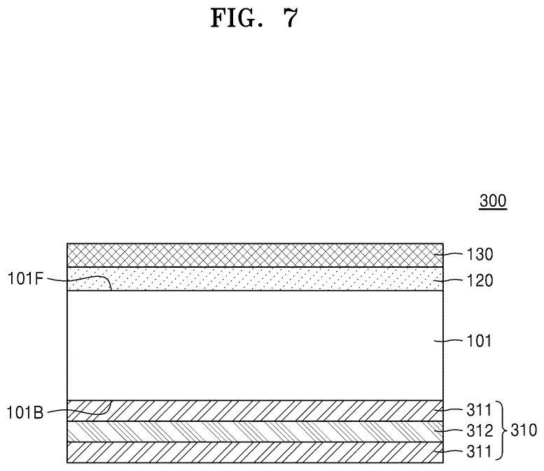

FIGS. 6 and 7 are cross-sectional views of 2D material growth substrates 200 and 300 according to other exemplary embodiments.

Most of components included in the 2D material growth substrates 200 and 300 to be described below and materials of the components may be substantially the same as or similar to the descriptions above with reference to FIGS. 1 to 5. Thus, for convenience of explanation, aspects different from the 2D material growth substrate 100 described above are described in detail below.

Referring to FIG. 6, a 2D material growth substrate 200 may include a dopant 210 on an interface between back-side surface 101B of the semiconductor substrate 101 and the strain control buffer layer 110. For each of the semiconductor substrate 101 and the strain control buffer layer 110 to apply a desired tensile strain or compressive strain to the 2D material layer 130, the following conditions may have to be satisfied.

A first thermal expansion coefficient of a material included in the semiconductor substrate 101 may be different from a second thermal expansion coefficient of a material included in the strain control buffer layer 110. For example, the material included in the semiconductor substrate 101 may be different from the material included in the strain control buffer layer 110.

A first thickness of the semiconductor substrate 101 may be different from a second thickness of the strain control buffer layer 110. For example, the second thickness may be less than the first thickness, in consideration of the warpage of the semiconductor substrate 101.

By forming the strain control buffer layer 110 having a selected thickness (or second thickness) and including a material different from the material of the semiconductor substrate 101, a fourth thermal expansion coefficient may be obtained by combining the semiconductor substrate 101 and the strain control buffer layer 110. In other words, through a back-side engineering process, the semiconductor substrate 101 and the strain control buffer layer 110 may have the fourth thermal expansion coefficient, which is substantially the same as or similar to a third thermal expansion coefficient of a material included in the 2D material layer 130.

As the second thickness of the strain control buffer layer 110 increases, it is more likely that an environment may be provided for making the fourth thermal expansion coefficient and the third thermal expansion coefficient the same. But proportionately, the warpage of the semiconductor substrate 101 may increase. To reduce the bonding force between the semiconductor substrate 101 and the strain control buffer layer 110, the dopant 210 may be applied to the interface between the back-side surface 101B of the semiconductor substrate 101 and the strain control buffer layer 110. For example, the dopant 210 applied in the 2D material growth substrate 200 may not be configured to form a doping area. Rather, the dopant 210 may be configured to reduce the bonding force between different types of materials on the interface.

The dopant 210 may include, for example, any one material selected from boron (B), phosphorus (P), arsenic (As), silicon (Si), and germanium (Ge), but is not limited thereto.

Referring to FIG. 7, a 2D material growth substrate 300 may include a strain control buffer layer 310 having a multilayer structure on the back-side surface 101B of the semiconductor substrate 101.

For each of the semiconductor substrate 101 and the strain control buffer layer 310 to apply a desired tensile strain or compressive strain to the 2D material layer 130, the following conditions may have to be satisfied.

A first thermal expansion coefficient of a material included in the semiconductor substrate 101 may be different from a second thermal expansion coefficient of a material included in the strain control buffer layer 310. For example, the material included in the semiconductor substrate 101 may be different from the material included in the strain control buffer layer 310.

In some embodiments, the strain control buffer layer 310 may have a multilayer structure in which a first strain control buffer layer 311 and a second strain control buffer layer 312 having different materials from each other may be alternately stacked. For example, the first strain control buffer layer 311 may include silicon oxide and the second strain control buffer layer 312 may include silicon nitride. By forming the strain control buffer layer 310 as a structure including a stack of materials having different thermal expansion coefficients, the strain control buffer layer 310 may have a desired thermal expansion coefficient, while the warpage of the semiconductor substrate 101 may be controlled.

FIG. 7 illustrates that the first strain control buffer layer 311 may include two layers and the second strain control buffer layer 312 may include one layer. However, the strain control buffer layer 310 is not limited thereto. For example, the strain control buffer layer 310 may include the first strain control buffer layer 311 including three or more layers and the second strain control buffer layer 312 including two or more layers.

By forming the strain control buffer layer 310 having a selected thickness and including a material different from the material of the semiconductor substrate 101, a fourth thermal expansion coefficient may be obtained by combining the semiconductor substrate 101 and the strain control buffer layer 310. In other words, through a back-side engineering process, the semiconductor substrate 101 and the strain control buffer layer 310 may have the fourth thermal expansion coefficient, which is substantially the same as or similar to a third thermal expansion coefficient of a material included in the 2D material layer 130.

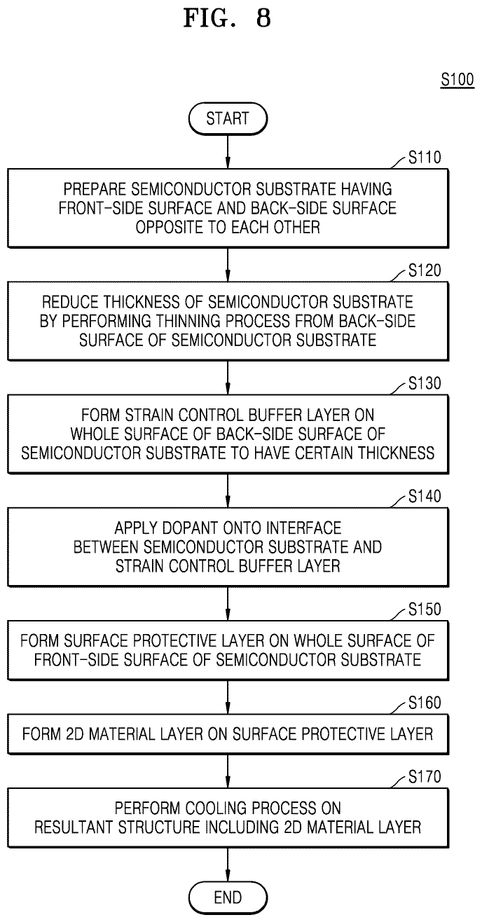

FIG. 8 is a flowchart of a method S100 of manufacturing a 2D material growth substrate, according to an embodiment.

In some embodiments, a specific order of operations of the method S100 may be different from the order described below. For example, two operations that are sequentially described may be substantially simultaneously performed or may be performed in an order opposite to the described order.

In detail, the method S100 of manufacturing a 2D material growth substrate according to an embodiment may include an operation S110 of preparing a semiconductor substrate including a front-side surface and a back-side surface that are opposite each other. The method S100 may include an operation S120 of reducing the thickness of the semiconductor substrate by performing a thinning process from the back-side surface of the semiconductor substrate. The method S100 may include an operation S130 of forming a strain control buffer layer having a selected thickness on the back-side surface of the semiconductor substrate. The method S100 may include an operation S140 of applying a dopant onto an interface between the semiconductor substrate and the strain control buffer layer. The method S100 may include an operation S150 of forming a surface protective layer on the front-side surface of the semiconductor substrate. The method S100 may include an operation S160 of forming a 2D material layer on the surface protective layer. The method S100 may include an operation S170 of performing a cooling process on a resultant structure including the 2D material layer.

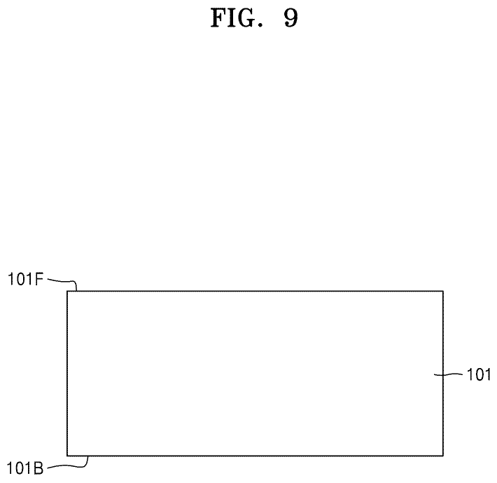

The technical characteristics with respect to each of the operations S110 to S170 are described in detail with reference to FIGS. 9 to 14 below.

FIGS. 9 to 14 are cross-sectional views in a process order for describing the method S100 of manufacturing a 2D material growth substrate, according to an embodiment.

Referring to FIG. 9, the semiconductor substrate 101 may be prepared (e.g., step S110).

The semiconductor substrate 101 may include any one material selected from a first group including silicon (Si), silicon oxide, silicon nitride, silicon carbide, sapphire, and metal oxide.

According to some embodiments, the semiconductor substrate 101 may include a monocrystalline semiconductor material. For example, the semiconductor substrate 101 may include a wafer including a semiconductor material, such as Si, as a monocrystalline type. The semiconductor substrate 101 may include a Group III element or a Group V element and may include an oxygen (O) element as impurities. The Group III element may include, for example, boron, and the Group V element may include, for example, phosphorus.

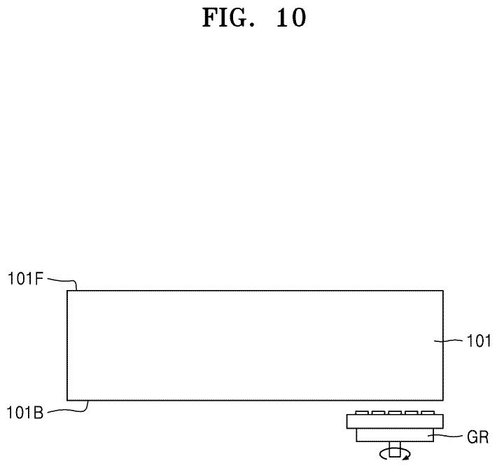

Referring to FIG. 10, the thinning process may be performed from the back-side surface 101B of the semiconductor substrate 101 (e.g., step S120).

According to some embodiments, as illustrated in FIG. 10, as the thinning process to reduce the thickness of the semiconductor substrate 101, a polishing process may be performed on the back-side surface 101B of the semiconductor substrate 101 by using a grinder GR. The polishing process may include a chemical and mechanical polishing process.

According to other embodiments (not shown in FIG. 10), as the thinning process to reduce the thickness of the semiconductor substrate 101, an etch process may be performed on the back-side surface 101B of the semiconductor substrate 101 by using an etch-back process. The etch process may include a dry etch process or a wet etch process.

According to other embodiments, the thinning process to reduce the thickness of the semiconductor substrate 101 may be omitted.

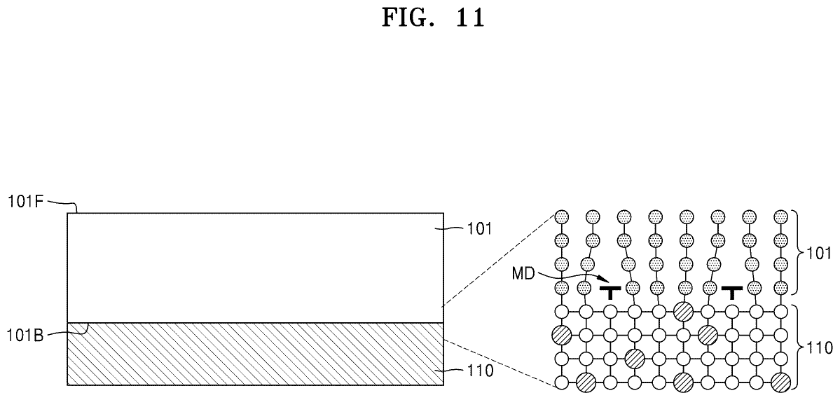

Referring to FIG. 11, the strain control buffer layer 110 may be formed on the back-side surface 101B of the semiconductor substrate 101, the back-side surface 101B having the reduced thickness due to the thinning process (e.g., step S130).

The strain control buffer layer 110 having a selected thickness may be formed on the back-side surface 101B of the semiconductor substrate 101. The strain control buffer layer 110 may be formed on the back-side surface 101B of the semiconductor substrate 101 by using at least one of a CVD process, a low-pressure CVD process, a plasma-enhanced CVD process, an organic metal CVD process, an ALD process, and an epitaxial process.

In some embodiments, the strain control buffer layer 110 may include a material selected from the first group including silicon (Si), silicon oxide, silicon nitride, silicon carbide, sapphire, and metal oxide, wherein the material included in the strain control buffer layer 110 may be different from a material included in the semiconductor substrate 101. For example, the semiconductor substrate 101 and the strain control buffer layer 110 may include the materials having different thermal expansion coefficients.

Accordingly, because the semiconductor substrate 101 and the strain control buffer layer 110 may include the materials having different thermal expansion coefficients, a grid misalignment may occur, and in some areas, a misfit dislocation (MD) may be generated. However, the MD may be mainly formed on an interface between the semiconductor substrate 101 and the strain control buffer layer 110, and thus, may seldom affect the front-side surface 101F of the semiconductor substrate 101.

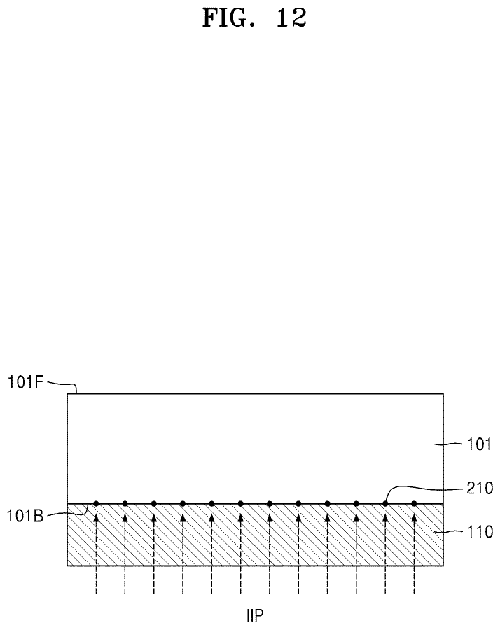

Referring to FIG. 12, the dopant 210 may be applied to the interface between the semiconductor substrate 101 and the strain control buffer layer 110 (e.g., step S140).

According to some embodiments, to reduce the warpage of the semiconductor substrate 101, as a means to reduce the bonding force between the semiconductor substrate 101 and the strain control buffer layer 110, an ion injection process IIP, in which the dopant 210 is applied onto the interface between the back-side surface 101B of the semiconductor substrate 101 and the strain control buffer layer 110, may be performed.

For example, the dopant 210 applied in the 2D material growth substrate 200 according to the present embodiment may not be configured to form a doping area. Rather, the dopant 210 may be configured to reduce the bonding force between different types of materials on the interface. The dopant 210 used in the ion injection process IIP may include, for example, any one material selected from boron (B), phosphorus (P), arsenic (As), silicon (Si), and germanium (Ge), but is not limited thereto.

According to other embodiments, the ion injection process IIP may be omitted.

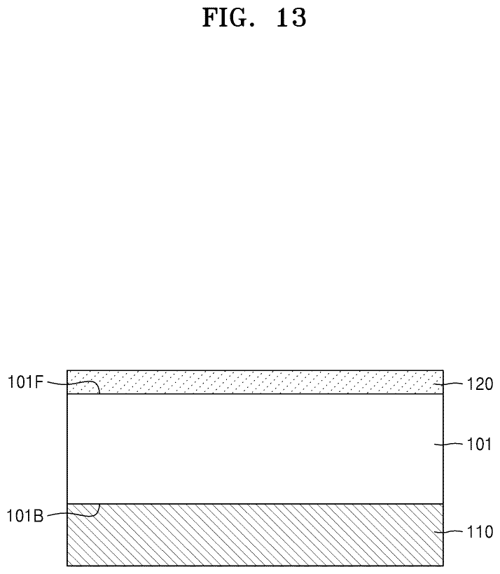

Referring to FIG. 13, the surface protective layer 120 may be formed on the front-side surface 101F of the semiconductor substrate 101 on which the strain control buffer layer 110 is formed (e.g., step S150).

The surface protective layer 120 may be formed on the front-side surface 101F of the semiconductor substrate 101 and may have a third thickness (e.g., a thickness of the surface protective layer 120). The surface protective layer 120 may be formed on the front-side surface 101F of the semiconductor substrate 101 by using any one process selected from among a thermal oxidation process, a plasma oxidation process, and a wet oxidation process.

In some embodiments, the surface protective layer 120 may include an oxide layer. In particular, when the semiconductor substrate 100 includes a semiconductor material, such as Si, as a monocrystalline type, the surface protective layer 120 may include a silicon oxide layer. For example, the silicon oxide layer may include SiO2, BSG, PSG, BPSG, USG, TEOS, or a combination thereof, but is not limited thereto.

The surface protective layer 120 may perform a function of resolving defects formed on the front-side surface 101F of the semiconductor substrate 101. For example, the surface protective layer 120 may reduce the effect by the crystalline edge surface by removing the dangling bond formed on the front-side surface 101F of the semiconductor substrate 101.

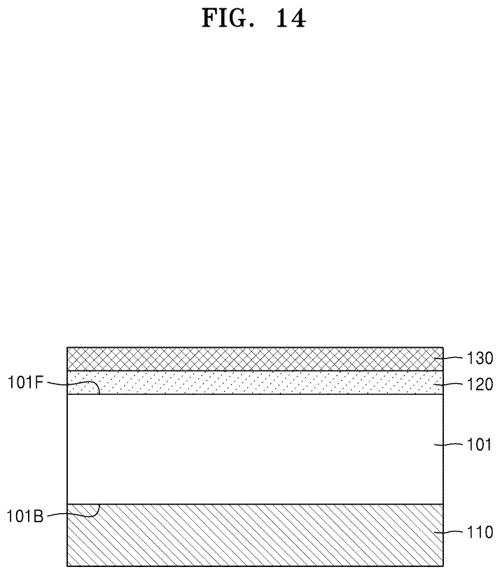

Referring to FIG. 14, the 2D material layer 130 may be formed on the surface protective layer 120 on the front-side surface 101F of the semiconductor substrate 101, the defects of which are resolved (e.g., step S160).

The 2D material layer 130 may be formed on the surface protective layer 120 to have a fourth thickness (e.g., thickness of the 2D material layer 130). For example, the 2D material layer 130 may include transition metal dichalcogenide, black phosphorus, or graphene, but is not limited thereto.

The transition metal dichalcogenide is a compound of a transition metal and a chalcogen element. The transition metal may include, for example, at least one of molybdenum (Mo), tungsten (W), niobium (Nb), tin (Sn), vanadium (V), tantalum (Ta), titanium (Ti), zirconium (Zr), hafnium (Hf), technetium (Tc), and rhenium (Re). The chalcogen element may include, for example, at least one of sulfur(S), selenium (Se), and tellurium (Te). For example, the transition metal dichalcogenide may include any one material selected from the group consisting of MoS₂, WS₂, TaS₂, HfS₂, ReS₂, TiS₂, NbS₂, SnS₂, MoSe₂, WSe₂, TaSe₂, HfSe₂, ReSe₂, TiSe₂, NbSe₂, SnSe₂, MoTe₂, WTe₂, TaTe₂, HfTe₂, ReTe₂, TiTe₂, NbTe₂, and SnTe₂, but is not limited thereto.

The black phosphorus is a 2D material in which phosphorus atoms are two-dimensionally combined. The graphene is a 2D material in which carbon atoms are two-dimensionally combined.

The 2D material layer 130 may further include a certain dopant to control electron mobility. For example, the 2D material layer 130 may be doped with a p-type dopant or an n-type dopant. The p-type dopant or n-type dopant may be doped by ion injection or chemical doping.

To reduce the temperature of a resultant structure including the 2D material layer 130, a cooling process may be performed (e.g., step S170).

Referring to FIGS. 1 to 5 again, according to the 2D material growth substrate 100 according to an embodiment, the combined thermal expansion coefficient of the semiconductor substrate 101 and the strain control buffer layer 110 may be substantially the same as or similar to the thermal expansion coefficient of the 2D material layer 130 in the cooling process, and thus, regardless of the cooling process, a desired strain (tensile strain or compressive strain) may be provided to the 2D material layer 130.

As a result, the 2D material growth substrate 100 manufactured through the method S100 (see FIG. 8) may be used to manufacture the semiconductor device 10 (see FIG. 15) having high integration and excellent electrical characteristics.

FIG. 15 is a cross-sectional view of the semiconductor device 10 according to an embodiment.

Referring to FIG. 15, the semiconductor device 10 may include the 2D material growth substrate 100.

The 2D material growth substrate 100 may include the semiconductor substrate 101. The semiconductor substrate 101 may include insulating substrates including various materials. The semiconductor substrate 101 may further include, for example, an impurity area formed by doping, an electronic device, such as a transistor, etc., or a peripheral circuit configured to select and control a memory cell storing data.

A channel region CH may be arranged on the semiconductor substrate 101. The channel region CH may be included in the 2D material layer 130. The 2D material layer 130 may denote a semiconductor material having a layer structure in which composed atoms are two-dimensionally combined. The characteristics and the configuration of the 2D material layer 130 are the same as described above.

To be used as the channel region CH, a certain dopant to control electron mobility of the 2D material layer 130 may be provided. For example, the 2D material layer 130 may be doped with a p-type dopant or an n-type dopant.

A gate dielectric layer 140 may be arranged above a middle portion of the channel region CH, and a gate electrode 150 may be arranged above the gate dielectric layer 140.

The gate dielectric layer 140 may include, for example, silicon oxide, silicon nitride, a high-dielectric material, or a combination thereof, but is not limited thereto. The high dielectric material may refer to a material having a higher dielectric constant than silicon oxide.

The gate electrode 150 may include, for example, metal, conductive nitride, or conductive oxide. The metal may include, for example, at least one of gold (Au), titanium (Ti), tungsten (W), molybdenum (Mo), platinum (Pt), and nickel (Ni). The conductive nitride may include, for example, TiN, TaN, WN, etc. The conductive oxide may include, for example, indium tin oxide (ITO), indium zinc oxide (IZO), etc.

A first electrode 161 and a second electrode 162 may be arranged above both sides of the channel region CH. The first electrode 161 and the second electrode 162 may be arranged to be in contact with upper surfaces (for example, a source area and a drain area) of both sides of the channel region CH. Thus, a planar contact may be formed between the first electrode 161 and the second electrodes 162 and both sides of the channel region CH.

Each of the first electrode 161 and the second electrode 162 may include, for example, metal, conductive nitride, or conductive oxide. The metal may include, for example, at least one of gold (Au), titanium (Ti), tungsten (W), molybdenum (Mo), platinum (Pt), and nickel (Ni). The conductive nitride may include, for example, TiN, TaN, WN, etc. The conductive oxide may include, for example, ITO, IZO, etc.

The 2D material growth substrate 100 included in the semiconductor device 10 according to an embodiment may control the electrical characteristics by using, for the 2D material layer 130, the strain generated due to the difference between thermal expansion coefficients of materials according to the strain control buffer layer 110 formed on the back-side surface 101B of the semiconductor substrate 101, as described above.

According to some embodiments, when the semiconductor device 10 operates as an n-type transistor, strain to increase the mobility of electrons is required. The semiconductor device 10 according to an embodiment may include the 2D material growth substrate 100 including the 2D material layer 130 having tensile strain.

According to other embodiments, when the semiconductor device 10 operates as a p-type transistor, strain to increase the mobility of holes is required. The semiconductor device 10 according to an embodiment may include the 2D material growth substrate 100 including the 2D material layer 130 having compressive strain.

As a result, the 2D material growth substrate 100 included in the semiconductor device 10 according to an embodiment may be used to manufacture the semiconductor device 10 having high integration and excellent electrical characteristics.

While the present disclosure has been particularly shown and described with reference to example embodiments thereof, it will be understood that various changes in form and details may be made therein without departing from the scope of the following claims.

What is claimed is:

1. A two-dimensional (2D) material growth substrate, comprising:
a semiconductor substrate having a first surface and a second surface opposite to the first surface;
a strain control buffer layer formed on the second surface of the semiconductor substrate;
a surface protective layer formed on the first surface of the semiconductor substrate; and
a 2D material layer formed on the surface protective layer and configured to generate one of a tensile strain and a compressive strain,
wherein the semiconductor substrate and the strain control buffer layer comprise materials having different thermal expansion coefficients, and a combined thermal expansion coefficient of the semiconductor substrate and the strain control buffer layer is substantially similar to a thermal expansion coefficient of the 2D material layer.

2. The 2D material growth substrate of claim 1, wherein:
the semiconductor substrate comprises a first material; and
the strain control buffer layer comprises a second material different from the first material,
wherein the first material and the second material are selected from a group of materials including silicon, silicon oxide, silicon nitride, silicon carbide, sapphire, and metal oxide.

3. The 2D material growth substrate of claim 2, wherein:
the first material comprises silicon;
the surface protective layer comprises silicon oxide; and
the surface protective layer is configured to remove a dangling bond of the silicon existing on the first surface of the semiconductor substrate.

4. The 2D material growth substrate of claim 1, wherein the 2D material layer further comprises a dopant.

5. The 2D material growth substrate of claim 4, wherein:
the dopant is an n-type dopant; and
the 2D material layer generates the tensile strain.

6. The 2D material growth substrate of claim 4, wherein:
the dopant is a p-type dopant, and
the 2D material layer generates the compressive strain.

7. The 2D material growth substrate of claim 1, further comprising:
a dopant on an interface between the second surface of the semiconductor substrate and the strain control buffer layer.

8. The 2D material growth substrate of claim 7, wherein the dopant comprises one of boron (B), phosphorus (P), arsenic (As), silicon (Si), and germanium (Ge).

9. The 2D material growth substrate of claim 1, wherein the 2D material layer comprises one of a transition metal dichalcogenide, black phosphorus, and graphene.

10. The 2D material growth substrate of claim 9, wherein the transition metal dichalcogenide comprises:
one metal element selected from molybdenum (Mo), tungsten (W), niobium (Nb), tin (Sn), vanadium (V), tantalum (Ta), titanium (Ti), zirconium (Zr), hafnium (Hf), technetium (Tc), and rhenium (Re); and
one chalcogen element selected from sulfur(S), selenium (Se), and tellurium (Te).

11. A method of manufacturing a two-dimensional (2D) material growth substrate, comprising:
preparing a semiconductor substrate having a first surface and a second surface opposite to the first surface;
forming a strain control buffer layer on the second surface of the semiconductor substrate;
applying a dopant to an interface between the semiconductor substrate and the strain control buffer layer;
forming a surface protective layer on the first surface of the semiconductor substrate; and
forming a 2D material layer on the surface protective layer, the 2D material layer being configured to generate one of a tensile strain and a compressive strain,
wherein the semiconductor substrate and the strain control buffer layer comprise materials having different thermal expansion coefficients, and a combined thermal expansion coefficient of the semiconductor substrate and the strain control buffer layer is substantially similar to a thermal expansion coefficient of the 2D material layer.

12. The method of claim 11, further comprising:
selecting a thickness of the strain control buffer layer such that the combined thermal expansion coefficient of the semiconductor substrate and the strain control buffer layer is substantially similar to the thermal expansion coefficient of the 2D material layer.

13. The method of claim 11, wherein the applying the dopant is configured to reduce a bonding force between the second surface of the semiconductor substrate and the strain control buffer layer.

14. The method of claim 11, wherein forming the surface protective layer comprises forming an oxide layer by using one of a thermal oxidation process, a plasma oxidation process, and a wet oxidation process.

15. The method of claim 11, further comprising:
after the preparing the semiconductor substrate, reducing a thickness of the semiconductor substrate by performing a thinning process from the second surface of the semiconductor substrate; and
after forming the 2D material layer, performing a cooling process on a resultant structure comprising the semiconductor substrate, the strain control buffer layer, and the 2D material layer.

16. A semiconductor device, comprising:
a semiconductor substrate having a first surface and a second surface opposite to the first surface;
a strain control buffer layer formed on the second surface of the semiconductor substrate;
a surface protective layer formed on the first surface of the semiconductor substrate;
a two-dimensional (2D) material layer formed on the surface protective layer and configured to generate one of a tensile strain and a compressive strain;
a first electrode and a second electrode formed on the 2D material layer;
a gate electrode formed between the first electrode and the second electrode; and
a gate dielectric layer formed between the 2D material layer and the gate electrode,
wherein the semiconductor substrate and the strain control buffer layer comprise materials having different thermal expansion coefficients, and a combined thermal expansion coefficient of the semiconductor substrate and the strain control buffer layer is substantially similar to a thermal expansion coefficient of the 2D material layer.

17. The semiconductor device of claim 16, wherein:
the semiconductor substrate comprises silicon;
the surface protective layer comprises silicon oxide; and
the strain control buffer layer comprises one of silicon, silicon oxide, silicon nitride, silicon carbide, sapphire, and metal oxide.

18. The semiconductor device of claim 16, wherein:
the 2D material layer comprises an n-type dopant; and
a thermal expansion coefficient of the strain control buffer layer is selected such that the 2D material layer generates the tensile strain.

19. The semiconductor device of claim 16, wherein:
the 2D material layer comprises a p-type dopant; and
a thermal expansion coefficient of the strain control buffer layer is selected such that the 2D material layer generates the compressive strain.

20. The semiconductor device of claim 16, wherein:
the 2D material layer below the gate electrode operates as a channel region of a transistor; and
the first electrode comprises a source electrode and the second electrode comprises a drain electrode.
